(19) United States
(12) Patent Application Publication
(10) Pub. No.: US 2026/0107483 A1
(43) Pub. Date: Apr. 16, 2026

(54) SEMICONDUCTOR DEVICE AND FORMATION METHOD THEREOF

(71) Applicant: TAIWAN SEMICONDUCTOR MANUFACTURING COMPANY, LTD., Hsinchu (TW)

(72) Inventors: Bo-Jiun LIN, Hsinchu County (TW); Chih-Sheng CHANG, Hsinchu City (TW); Tung Ying LEE, Hsinchu City (TW)

(73) Assignee: TAIWAN SEMICONDUCTOR MANUFACTURING COMPANY, LTD., Hsinchu (TW)

(21) Appl. No.: 18/912,893

(22) Filed: Oct. 11, 2024

(51) Int. Cl. H10B 53/30; C23C 16/455; H10B 63/00

(52) U.S. Cl. CPC H10D 1/694; H10B 53/30; C23C 16/45529; H10B 63/00

(57) ABSTRACT

A method of forming a semiconductor device includes the following step. A bottom electrode is formed over a substrate. A deposition process including one or more repetitions of a deposition cycle to is performed form a ferroelectric layer over the bottom electrode. The deposition process comprises performing a first deposition step including pulsing a first metal-containing precursor, pulsing a first oxidant reacting with the first metal-containing precursor to form a first monolayer, and performing a first plasma treatment to the first monolayer, and performing a second deposition step including pulsing a second metal-containing precursor, pulsing a second oxidant reacting with the second metal-containing precursor to form a second monolayer, and performing a second plasma treatment to the second monolayer. A top electrode is formed over the ferroelectric layer.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2 and 3 are cross-sectional views of a semiconductor device in various stages of fabrication in accordance with some embodiments of the present disclosure.

FIGS. 4A, 4B and 4C are cross-sectional views of semiconductor structures in accordance with some embodiments of the present disclosure.

FIGS. 5A, 5B and 5C show a stack including an HfO₂ layer over a substrate, a stack including a Hf_{0.5}Zr_{0.5}O₂ layer over a substrate, and a stack including a ZrO₂ layer over a substrate.

FIGS. 6 and 7A are cross-sectional views of a semiconductor device in various stages of fabrication in accordance with some embodiments of the present disclosure.

FIG. 7B is a chart of a polarization-voltage (P-V) hysteresis loop with respect to the semiconductor structure in FIG. 7A without a post anneal process, in which both of the bottom electrode and the top electrode include Ru, and the ferroelectric layer includes a thickness of about 4 nm to about 6 nm, such as about 5 nm.

FIGS. 8A-8H are cross-sectional views of a semiconductor device in various stages of fabrication in accordance with some embodiments of the present disclosure.

FIG. 9 illustrates a perspective view of an integrated chip having an FeRAM device.

FIG. 10 illustrates a perspective view of an FeFET device in accordance with some embodiments.

FIG. 11 illustrates a perspective view of an integrated chip having a ferroelectric tunnel junction (FTJ) in accordance with some embodiments.

FIGS. 12-14 show cross-sectional views of devices including MFM structures in accordance with some embodiments.

FIG. 15 shows a cross-sectional view of a device including metal-ferroelectric-insulator-metal (MFIM) structure in accordance with some embodiments.

FIG. 16 shows a cross-sectional view of a device including metal-ferroelectric-substrate (MFS) structure in accordance with some embodiments.

FIG. 17 shows a cross-sectional view of a device including metal-ferroelectric-substrate (MFS) structure in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

Ferroelectric materials are substances that can maintain and reverse their electric polarization with an external electric field. Ferroelectric materials can be used for ferroelectric devices such as Ferroelectric Random Access Memory (FeRAM), Ferroelectric field effect transistor (FeFET), ferroelectric tunnel junctions (FTJ) device, or ferroelectric memory field-effect transistor (FeMFET).

With continual reductions in minimum feature size, thicknesses of layers may be reduced. For example, the ferroelectric material in the ferroelectric devices may have a reduced thickness. However, thinner ferroelectric material requires a higher annealing temperature to obtain its ferroelectricity. When the ferroelectric material has a small thickness such as in a range from about 2 nm to about 7 nm, such as about 5 nm, the anneal temperature can be higher than back end of line (BEOL) process temperature which may be, for example, about 400 °C to about 450°C, such as about 400 °C.

To fulfill BEOL FeMFET application, a low-thermal budget process for forming ferroelectric material with high remnant polarization (Pᵣ), such as greater than 10 (µC/cm²), is required.

Embodiments of the present disclosure provide a process to form an anneal-free metal-ferroelectric-metal (MFM) structure with high remnant polarization (Pᵣ). Since the process is anneal-free, large memory window including low leakage performance and less metal oxidation concern can be achieved. The manufacturing yield can be improved. The anneal-free MFM structure can be applied to various memory structures such as FeRAM, FeFET, FTJ, or the like.

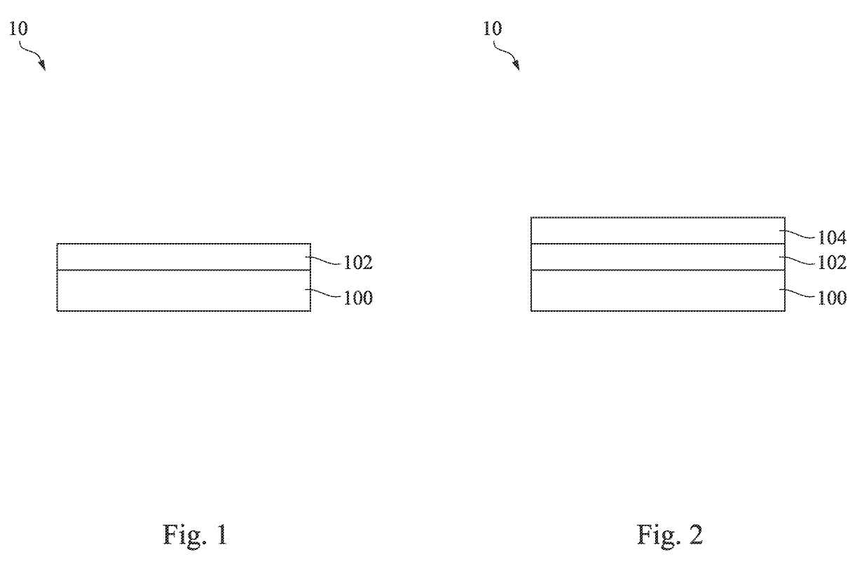

FIGS. 1, 2, 4A-4C, 8A-8H, 9 and 10 are cross-sectional views of a semiconductor structure 10 in various stages of fabrication in accordance with some embodiments of the present disclosure. Reference is made to FIG. 1. In some embodiments, a bottom electrode layer 102 is formed over a substrate such as using atomic layer deposition (ALD), chemical vapor deposition (CVD), low pressure CVD (LPCVD), physical vapor deposition (PVD), plating, evaporation, ion beam, energy beam, or other suitable method. In some embodiments, the bottom electrode layer 102 includes metal such as a transition metal. For example, the bottom electrode layer 102 can be a Ru-containing layer. That is, the bottom electrode layer can be Ru layer, Ru alloy layer, or a combination thereof. In some embodiments, the bottom electrode layer 102 is conformally formed on the substrate 100. The Ru-containing layer can enhance phase formation of octahedral/tetragonal (O/T) hafnium zirconium oxide (HZO), which will be discussed in greater detail below.

In some other embodiments, the bottom electrode layer 102 includes Pt, TiN, or a combination thereof. In some embodiments, the bottom electrode layer 102 has a thickness in a range from about 10 nm to about 20 nm, such as about 15 nm. In some embodiments, the substrate 100 is a silicon substrate with a desired doping concentration. In other embodiments, the substrate 100 may be a silicon germanium, BEOL oxide semiconductor, gallium arsenide, compound semiconductor, multi-layers semiconductor, silicon on insulator (SOI), germanium on insulator (GeOI), or the like.

Reference is made to FIG. 2. In some embodiments, a ferroelectric layer 104 is formed over the bottom electrode layer 102. The ferroelectric layer 104 can be referred to as a variable resistance layer. Since the ferroelectric layer 104 used as a memory cell may be regarded as storing a logical bit, where the variable resistance layer has increased resistance, the memory cell may be regarded as storing a “0” bit; where the variable resistance layer has reduced resistance, the memory cell may be regarded as storing a “1” bit, and vice-versa. A circuitry may be used to read the resistive state of the resistive switching element by applying a read voltage to the two electrodes and measuring the corresponding current through the variable resistance layer. If the current through the variable resistance layer is greater than some predetermined baseline current, the resistive switching element is deemed to be in a reduced resistance state, and therefore the RRAM cell is storing a logical “1.” On the other hand, if the current through the variable resistance layer is less than some predetermined baseline current, then the variable resistance layer is deemed to be in an increased resistance state, and therefore the memory cell is storing a logical “0.”

The ferroelectric layer 104 can include hafnium zirconium oxide (HZO). Ratio of elements in the ferroelectric layer 104 can be determined by suitable measurement techniques such as X-ray photoelectron spectroscopy (XPS). For example, an atomic concentration of Hf in the ferroelectric layer 104 may be substantially the same as an atomic concentration of Zr in the ferroelectric layer 104. In other words, the ferroelectric layer 104 comprises hafnium zirconium oxide with a hafnium atomic concentration and a zirconium atomic concentration substantially the same as the hafnium atomic concentration. In some embodiments, the Hf in the ferroelectric layer 104 has an atomic concentration of about 14.0 ± 0.05%. In some embodiments, the Zr in the ferroelectric layer 104 has an atomic concentration of about 12.8 ± 0.05%. In some embodiments, the ferroelectric layer 104 has an oxygen concentration in a range of about 73.2 ± 0.05%. In some embodiments, the ferroelectric layer 104 has a thickness in a range of about 1 nm to about 10 nm, such as about 2 nm to about 7 nm, such as about 5 nm.

In some embodiments where the ferroelectric layer 104 is formed by the ALD process, a deposition process includes one or more repetitions of a deposition cycle. Each deposition cycle includes an HfO₂ deposition step and a ZrO₂ deposition step.

Each of the HfO₂ deposition steps includes a first step, a second step and a third step. Each of the ZrO₂ deposition step includes a fourth step, a fifth step and a sixth step. In the first step, a first metal-containing precursor such as a first metal organic precursor is pulsed followed by pulsing an oxidant. After the first step is performed, the second step is performed. In the second step, a purge gas is introduced to purge out the first metal organic precursor and the oxidant. The purge gas may be any non-reactive gas with the first metal organic precursor, such as N₂, or any inert gas (He, Ne, Ar, Kr, etc.).

The first metal organic precursor including, for example, Hf precursor, such as Hf(NMe₂)₄ (tetrakis(dimethylamido)hafnium (TDMAH), is provided to chemisorb on a surface of the bottom electrode layer 102. The oxidant, such as water, reacts with the absorbed first metal organic precursor, forming a monolyaer of HfOₓ.

Further non-limiting examples of suitable Hf precursors include: Hf(O^{t}Bu)₄ (hafnium tert-butoxide, HTB), Hf(NEt₂)₄ (tetrakis(diethylamido)hafnium, TDEAH), Hf(NEtMe)₄ (tetrakis(ethylmethylamido)hafnium, TEMAH), Hf(NMe₂)₄ (tetrakis(dimethylamido)hafnium, TDMAH), Hf(mmp)₄ (hafnium methymethoxypropionate, Hf mmp), HfCl₄, (tetrakis(N,N′-dimethylacetamidinato)), Hf, Cp₂HfMe₂, Cp₂Hf(Me)OMe, (tBuCp)₂HfMe₂, CpHf(NMe₂)₃, and Hf(NⁱPr₂)₄. It is noted that Cp stands for cycclopentadienyl or alkylcyclopentadienyl; Me stands for methyl; Et stands for ethyl; and ⁱPr stands for iso-propyl. In the second step, an unreactive inert gas, such as Ar or N₂, is used for purging away the excess first metal organic precursor and the oxidant. After the second step, the third step is performed. The third step includes a plasma treatment using non-reactive gas with the first metal organic precursor or the oxidant, such as Ar, or any inert gas (N₂, He, Ne, Kr, etc.). The plasma treatment, in some instances, can allow the ferroelectric layer 104 to have ferroelectricity without using an additional anneal process or a post-anneal process and allow the ferroelectric layer 104 to keep high remnant polarization (Pᵣ) with low leakage current. In other words, the HfO₂ deposition step is free from an anneal process. In some embodiments, the third step is performed at a temperature lower than back end of line (BEOL) process temperature which may be, for example, about 400 °C to about 450°C, such as about 400 °C. For example, the third step can be performed at a temperature in a range from about 200°C to 300°C, such as 250°C.

After the third step is performed, the fourth step is performed. In the fourth step, firstly, the second metal organic precursor including, for example, tetrakis-(dimethylamino) zirconium (TDMAZ), or Tetrakis-(ethylmethylamino) zirconium (TEMAZ, Zr[N(C₂H₅)CH₃]₄) is pulsed to chemisorb on a surface of the monolayer of HfOₓ formed by the HfO₂ deposition step. The oxidant, such as water, is pulsed and reacts with the absorbed second metal organic precursor, forming a monolyaer of ZrOₓ. In the fifth step, an inert gas non-reactive to the second metal organic precursor and the oxidant, such as Ar or N₂, is used for purging away the excess second metal organic precursor and the oxidant. That is, the monolayer of HfOₓ and the monolyaer of ZrOₓ have different compositions.

After the fifth step, the sixth step is performed. The sixth step includes a plasma treatment using gas non-reactive with the first metal organic precursor and the oxidant, such as Ar, or any inert gas (N₂, He, Ne, Kr, etc.). The plasma treatment, in some instances, can allow the ferroelectric layer 104 to have ferroelectricity without using an additional anneal process and allow the ferroelectric layer 104 to keep high remnant polarization (Pᵣ) with low leakage current. In other words, the ZrO₂ deposition step is free from an anneal process. In some embodiments, the sixth step is performed at a temperature lower than back end of line (BEOL) process temperature which may be, for example, about 400 °C to about 450°C, such as about 400 °C. For example, the sixth step can be performed at a temperature in a range from about 200°C to 300°C, such as 250°C.

In some embodiments, the HfO₂ deposition step and the ZrO₂ deposition step are repeated until a desired thickness is achieved. A ratio of the HfO₂ deposition steps and the ZrO₂ deposition step may be tuned to control an atomic ratio of Hf/Zr in the ferroelectric layer 104. For example, the HfO₂ deposition steps is performed for about X times, and the ZrO₂ deposition step are performed for about Y times. In some embodiments, X is substantially the same as Y such that the atomic concentration of Hf in the ferroelectric layer 104 may be substantially the same as the atomic concentration of Zr in the ferroelectric layer 104. In other words, a ratio of X to Y is substantially equal to 1.

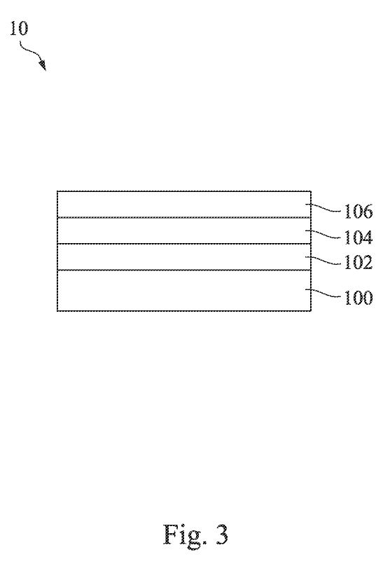

Reference is made to FIG. 3. In some embodiments, a top electrode layer 106 is formed over the ferroelectric layer 104. The top electrode layer 106 may be similar to the bottom electrode layer 102 in terms of material and formation methods. In some embodiments, the top electrode layer 106 has a thickness in a range from about 10 nm to about 20 nm, such as about 15 nm. In some embodiments, the top electrode layer 106 and the bottom electrode layer 105 can have substantially the same thickness.

In some embodiments where the bottom electrode layer 102 is Ru, the semiconductor structure 10 can have a high remnant polarization (Pᵣ), for example, in a range from about 18 µC/cm²to about 20 µC/cm² with low leakage current. For example, the leakage current can be in a range from about 10⁻⁸ A to 10⁻⁶ A. In some embodiments, the ferroelectric layer 104 can have a thickness in a range from about 5 nm to about 7 nm. Since the ferroelectric layer 104 can be formed with desired remnant polarization (Pᵣ) and low leakage current without using an anneal process, large memory window including low leakage performance and less metal oxidation concern can be achieved. For example, the memory window has an improvement of about 25% to about 30%. The manufacturing yield can be improved. BEOL FeMFET application can be fulfilled. For example, the yield can have an improvement of about 40% to about 50%. In some other embodiments, a wafer may include a plurality of dies each includes semiconductor structures similar to the semiconductor device 20. The memory window of a portion of the dies at the center of the wafer can be improved to be doubled.

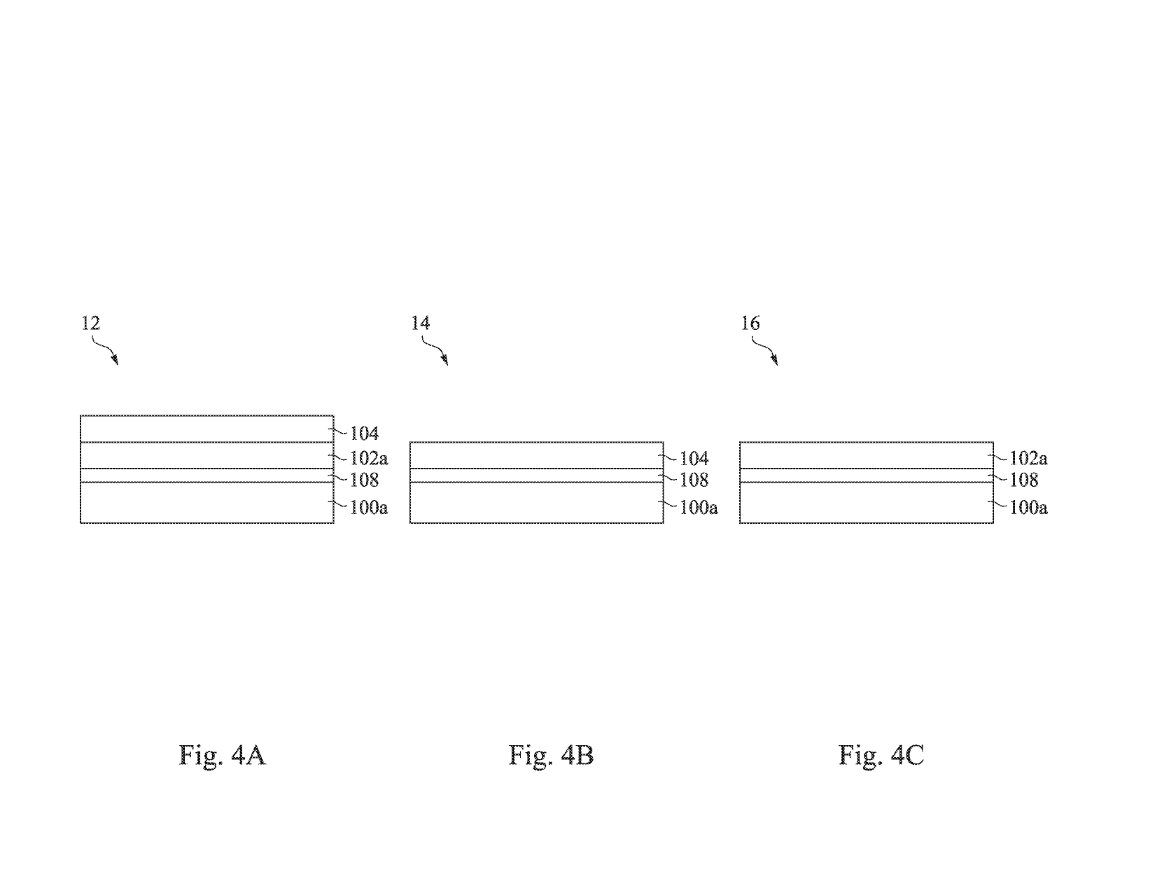

FIGS. 4A, 4B and 4C are cross-sectional views of semiconductor structures 12, 14 and 16 in accordance with some embodiments of the present disclosure. In FIG. 4A, the semiconductor structure 10 includes an oxide layer 108, a bottom electrode layer 102a made of Ru, and a ferroelectric layer 104 stacked over a substrate 100a in sequence. In FIG. 4B, the semiconductor structure 14 includes an oxide layer 108 and a ferroelectric layer 104 stacked over a substrate 100a in sequence. In FIG. 4C, the semiconductor structure 16 includes an oxide layer 108 and a bottom electrode layer 102a stacked over a substrate 100a in sequence. In some embodiments, the bottom electrode layer 102a can have a thickness in a range from about 2 nm to about 7 nm, such as about 5 nm. The semiconductor structures 12, 14 and 16 are free from treated with the anneal process.

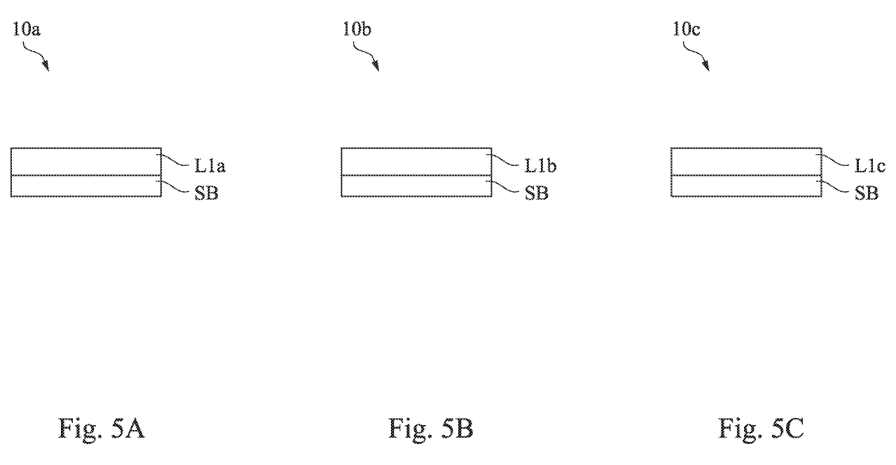

FIGS. 5A, 5B and 5C show a stack 10a including an HfO₂ layer L1a over a substrate SB, a stack 10b including an Hf_{0.5}Zr_{0.5}O₂ layer L1b over a substrate SB, and a stack 10c including a ZrO₂ layer L1c over a substrate SB. In FIG. 5A, the HfO₂ layer L1a can include a monoclinic crystal structure, which is a low symmetry phase. In FIG. 5B, the Hf_{0.5}Zr_{0.5}O₂ layer L1b can include an intermediate/orthorhombic crystal structure, which shows a ferroelectric phase. In FIG. 5C, the ZrO₂ layer L1c can include a tetragonal crystal structure, which shows a high symmetry phase.

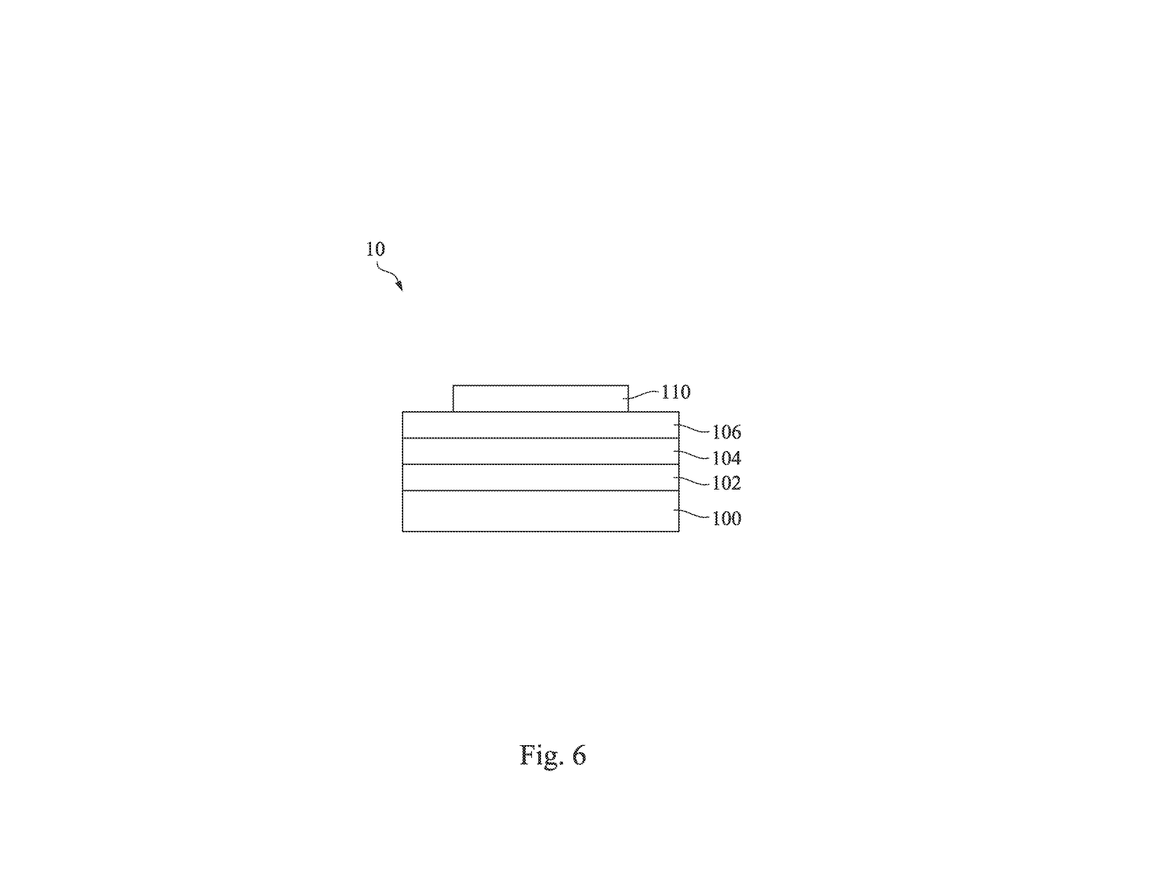

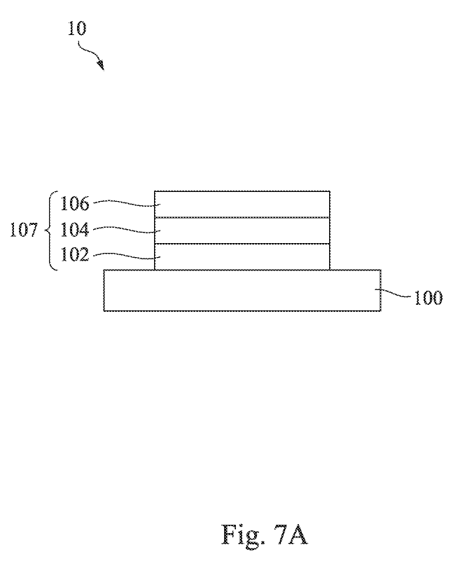

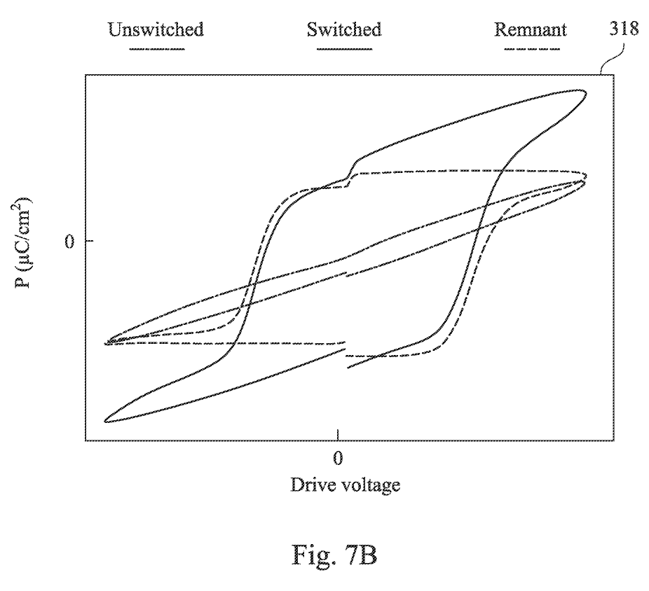

Reference is made to FIG. 6. A mask layer 110 is formed over the top electrode layer 106. In some embodiments, the mask layer 110 may be a photoresist material formed using a spin-on coating process, followed by patterning the photoresist material using suitable lithography techniques. For example, photoresist material is irradiated (exposed) and developed to remove portions of the photoresist material. In greater detail, a photomask (not shown) may be placed over the photoresist material, which may then be exposed to a radiation beam provided by a radiation source such as ultraviolet (UV) source, deep UV (DUV) source, extreme UV (EUV) source, and X-ray source. For example, the radiation source may be a mercury lamp having a wavelength of about 436 nm (G-line) or about 365 nm (I-line); a Krypton Fluoride (KrF) excimer laser with wavelength of about 248 nm; an Argon Fluoride (ArF) excimer laser with a wavelength of about 193 nm; a Fluoride (F₂) excimer laser with a wavelength of about 157 nm; or other light sources having an appropriate wavelength (e.g., below approximately 100 nm). In another example, the light source is an EUV source having a wavelength of about 13.5 nm or less. After the mask layer 110 is formed and patterned, the top electrode layer 106, the ferroelectric layer 104 and the bottom electrode layer 102 are etched using the mask layer 110 as an etch mask, exposing the substrate 100. The mask layer 110 is then removed such as using plasma ashing process. The resulting structure is shown in FIG. 7A. The bottom electrode layer 102, the ferroelectric layer 104 and the top electrode layer 106 can be collectively referred to as a metal-ferroelectric-metal (MFM) structure 107.

FIG. 7B is a chart 318 of a polarization-voltage (P-V) hysteresis loop with respect to the semiconductor structure 10 in FIG. 7A without a post anneal process, in which both of the bottom electrode layer 102 and the top electrode layer 106 include Ru, and the ferroelectric layer 104 includes a thickness of about 4 nm to about 6 nm, such as about 5 nm. In some embodiments, the remnant polarization (Pᵣ) in the chart 318 is about 16±2 µC/cm².

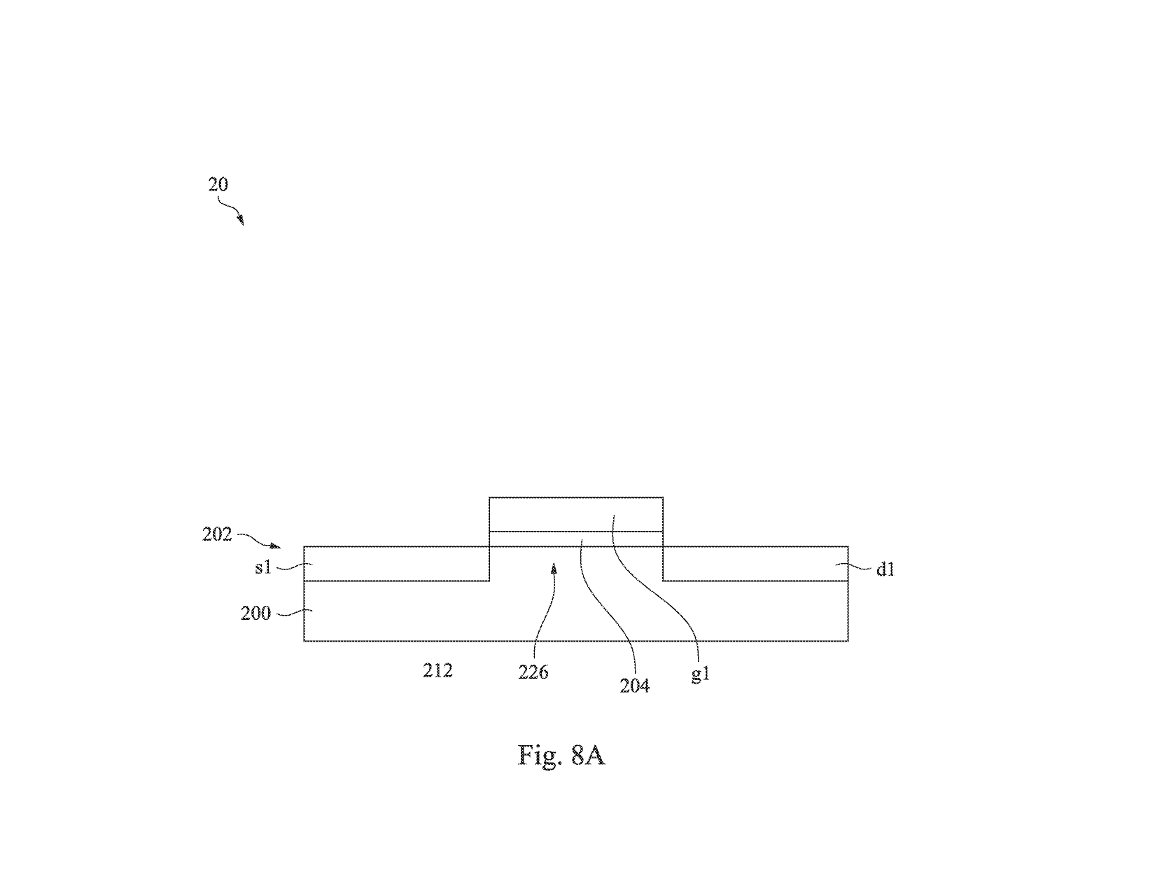

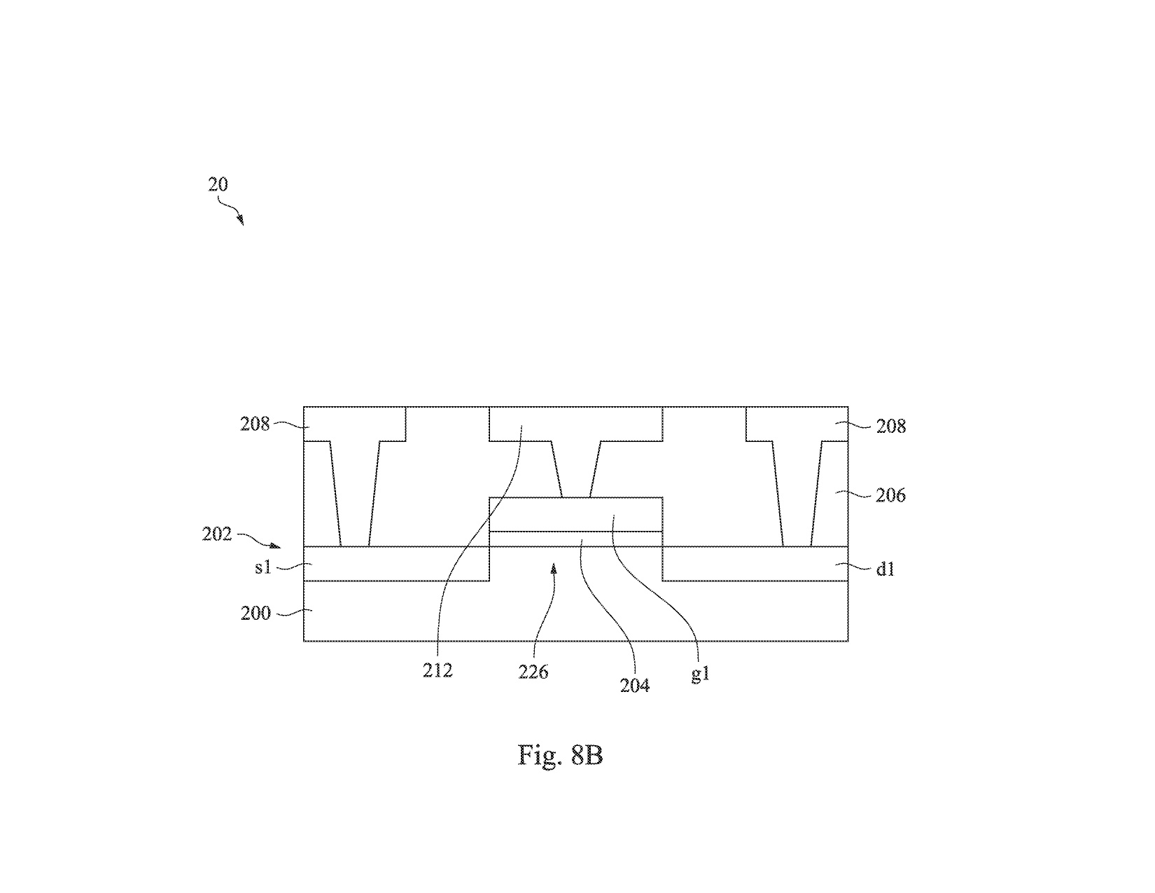

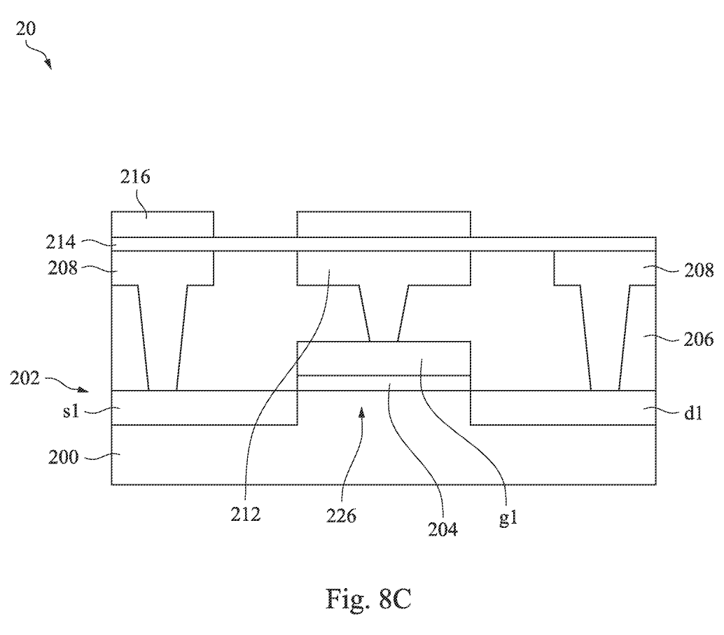

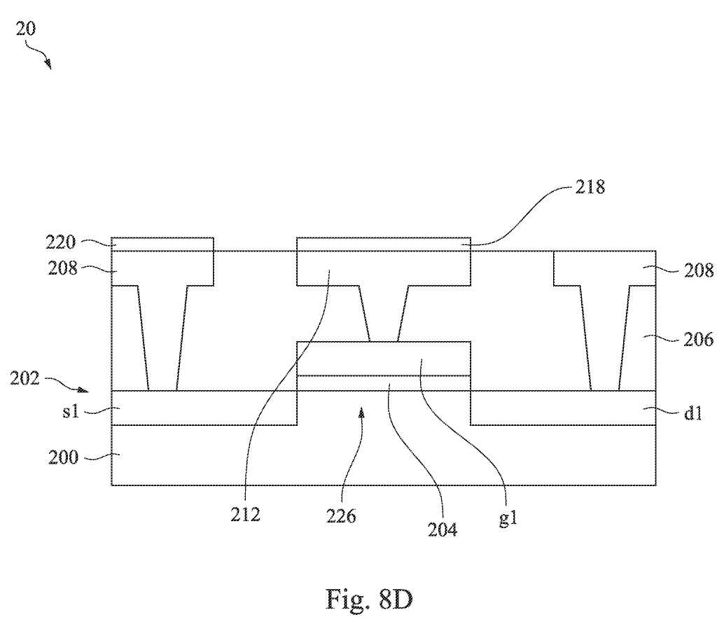

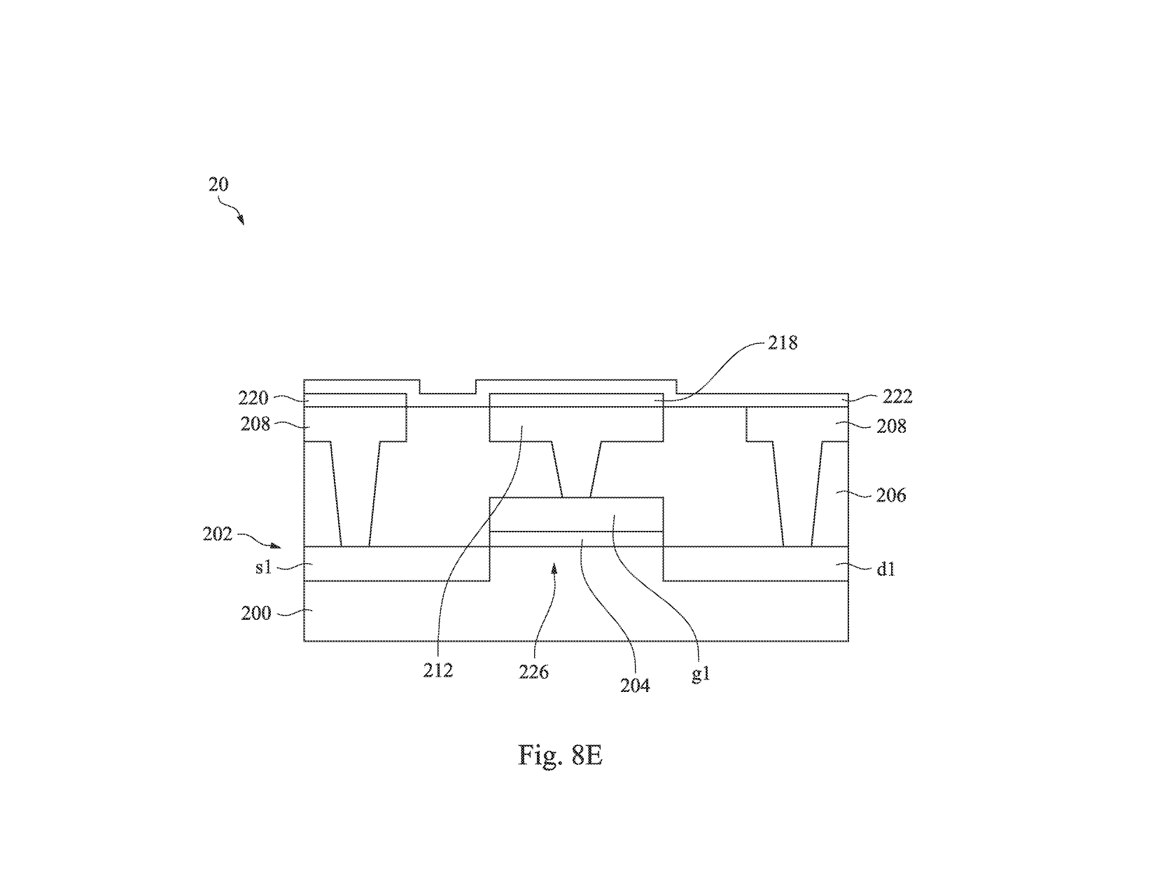

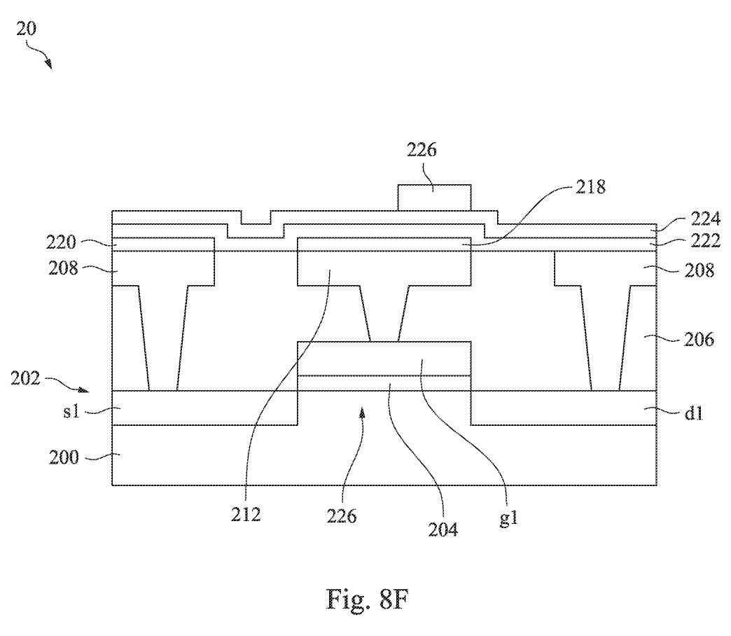

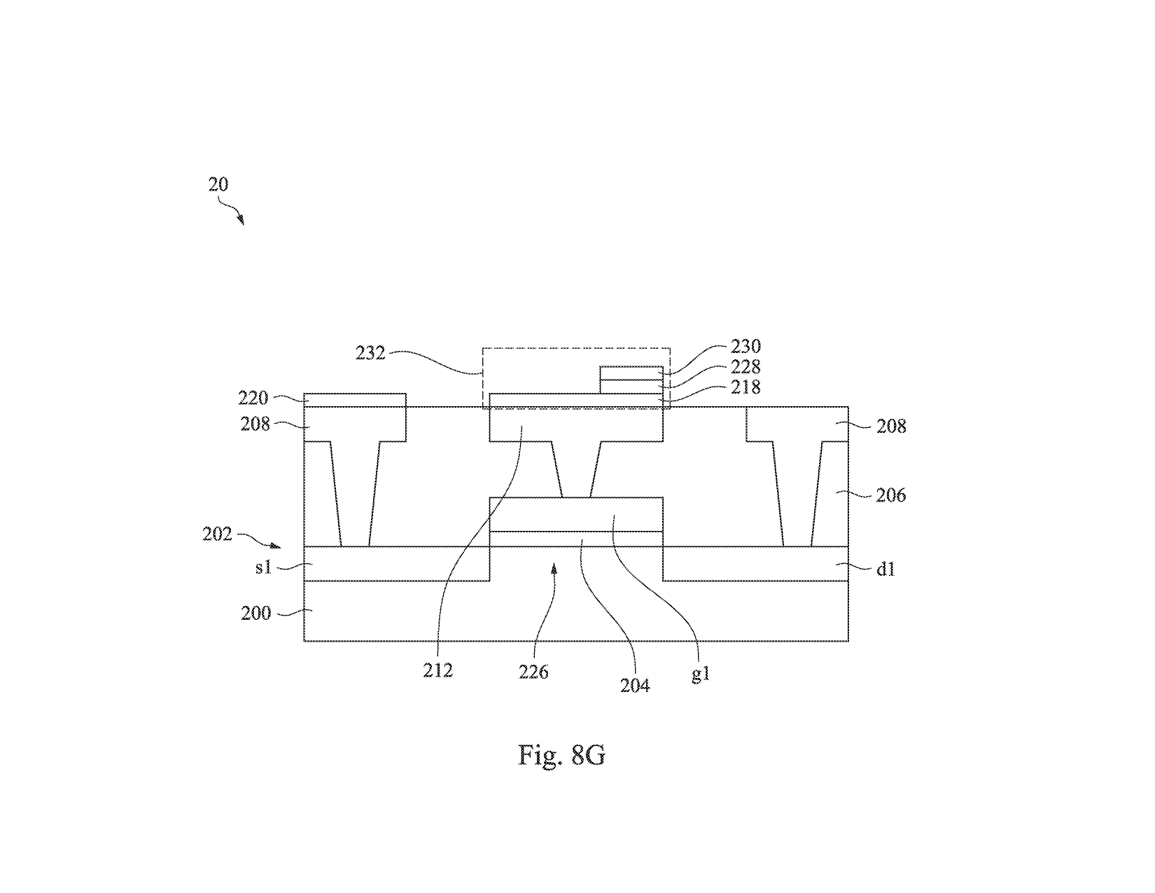

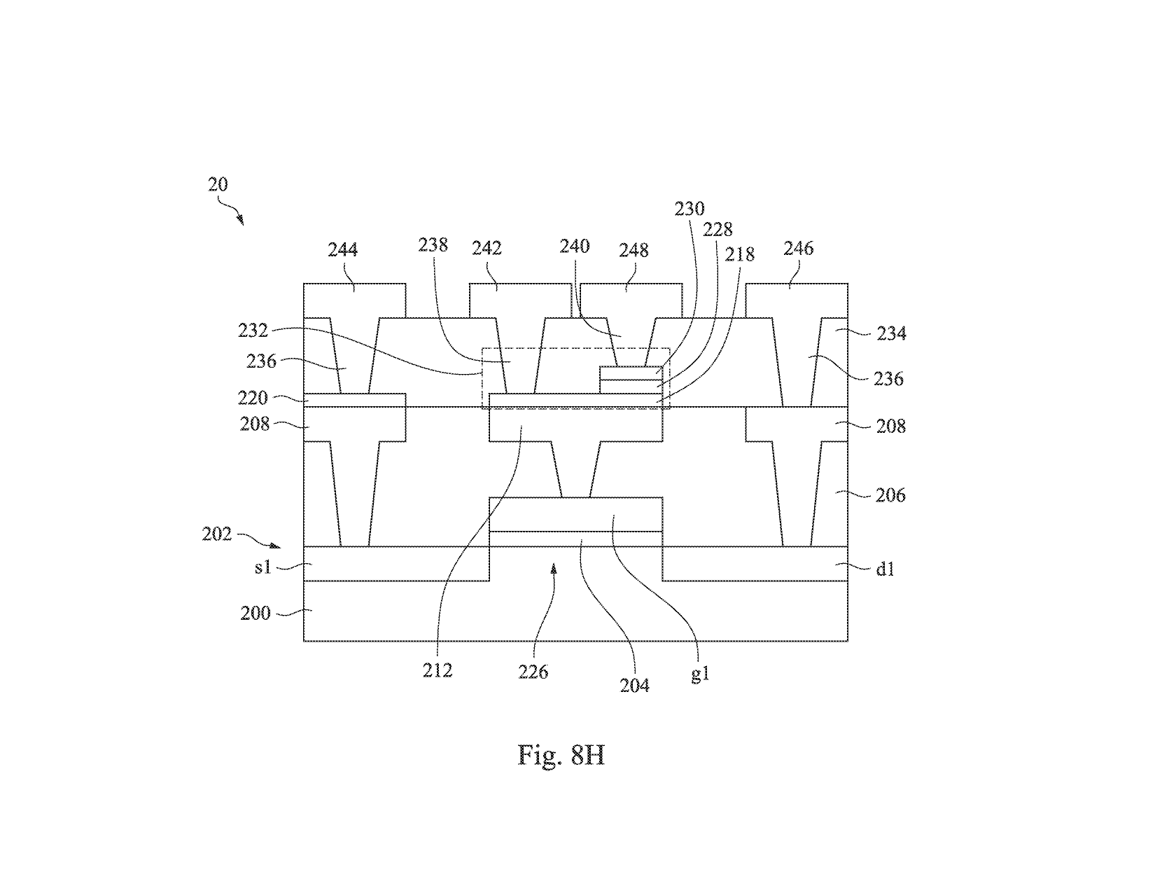

FIGS. 8A-8H are cross-sectional views of a semiconductor device 20 in various stages of fabrication in accordance with some embodiments of the present disclosure. Reference is made to FIG. 8A. The semiconductor device 20 may include a transistor 202 formed over a substrate 200. In some embodiments, the substrate 200 is a silicon substrate with a desired doping concentration. In other embodiments, the substrate 200 may be a silicon germanium, gallium arsenide, compound semiconductor, multi-layers semiconductor, silicon on insulator (SOI), germanium on insulator (GeOI), and the like. The transistor 202 includes source/drain regions s1/d1 and a gate electrode g1. In some embodiments, the gate electrode g1 including a polysilicon layer (not shown) formed over a gate oxide layer 204. In other embodiments, the gate electrode g1 may include a metal gate electrode formed over a gate dielectric layer with high dielectric constant (k). The gate electrode g1 may also include spacers (not shown) covering the corners between sidewalls of the gate electrode g1 and substrate 200. In some embodiments, a silicide layer (not shown) may be formed on the top of the gate electrode g1 and the source/drain regions s1/d1 of the transistor 202 by a silicide process, in order to reduce the resistance of the gate electrode g1 and diffusion regions. The silicide can be NiSi₂, CoSi₂, TiSi₂, or the like. The source/drain regions s1/d1 may include any acceptable material, such as appropriate for the device type, e.g., n-type. For example, the source/drain regions s1/d1 for an n-type device may include silicon, SiP, SiC, SiCP, the like, or a combination thereof. The source/drain regions s1/d1 may include any acceptable material, such as appropriate for the device type, e.g., p-type. For example, the source/drain regions s1/d1 for a p-type device may include SiGe, SiGeB, Ge, GeSn, or the like. A channel region 225 is formed below the gate electrode g1.

Reference is made to FIG. 8B. A first interlayer dielectric (ILD) layer 206 is formed over the gate electrode g1 and the source/drain regions s1/d1. After the first ILD layer 206 is formed, source/drain contact openings are formed through the first ILD layer 206. For example, the first ILD layer 206 may be patterned, for example, using photolithography and one or more etch processes. Conductive materials can be deposited in the source/drain contact openings of the first ILD layer 206. The conductive materials can include a conformal adhesion layer (not shown) formed in the exposed surfaces of the source/drain contact openings, a barrier layer (not shown) on the adhesion layer and a conductive layer on the barrier layer. The conductive layer can be deposited on the barrier layer and fill the source/drain contact openings. The adhesion layer may be or include titanium, tantalum, the like, or a combination thereof, and may be deposited by ALD, CVD, or another deposition technique. The barrier layer may be or include titanium nitride, titanium oxide, tantalum nitride, tantalum oxide, the like, or a combination thereof, and may be deposited by ALD, CVD, or another deposition technique. The conductive layer may be or include tungsten, cobalt, copper, ruthenium, aluminum, gold, silver, alloys thereof, the like, or a combination thereof, and may be deposited by CVD, ALD, PVD, or another deposition technique. After the conductive layer is deposited, excess conductive layer, barrier layer, and adhesion layer may be removed by using a planarization process, such as CMP, for example. Hence, top surfaces of the conductive materials and the first ILD layer 206 may be coplanar. The conductive materials may be referred to as source/drain contacts 208 and a gate contact 212. The source/drain contacts 208 penetrate the first ILD layer 206 to electrically connect to the source/ drain regions s1/d1 and provide landing areas for vias 236. The gate contact 212 penetrates through the first ILD layer 206 to contact the gate electrode g1 to electrically connect to the gate electrode g1.

Reference is made to FIG. 8C. In some embodiments, a bottom electrode layer 214 is formed over the gate contact 212, the source/drain contacts 208 and the first ILD layer 206. A mask layer 216 is formed over the bottom electrode layer 214. The mask layer 216 is similar to the mask layer 110 with respect to FIG. 6 in terms of composition and formation method thereof. After the mask layer 216 is formed and patterned, the bottom electrode layer 214 is etched using the mask layer 216 as an etch mask, exposing the first ILD layer 206 and one of the source/drain contacts 208. The mask layer 216 is then removed such as using plasma ashing process. The resulting structure is shown in FIG. 8D. Remaining portions of the bottom electrode layer 214 (see FIG. 8C) can be referred to as a bottom electrode 218 over the gate contact 212 and a conductive feature 220 over one of the source/drain contacts 208.

Reference is made to FIG. 8E. A ferroelectric layer 222 can be formed over the bottom electrode 218, the conductive feature 220 and the first ILD layer 206 using a process similar to the process as discussed previously with respect to FIG. 2. For example, the ferroelectric layer 222 can be formed by the ALD process which is the deposition cycle including one or more HfO₂ deposition steps and one or more ZrO₂ deposition step with respect to FIG. 2. Since the ferroelectric layer 222 can be formed with the desired remnant polarization (Pᵣ) and the low leakage current without using an anneal process, large memory window including low leakage performance and less metal oxidation concern can be achieved. The manufacturing yield can be improved.

Reference is made to FIG. 8F. A top electrode layer 224 is then formed over the ferroelectric layer 222. In some other embodiments, the top electrode layer 224 can include TiN, Pt, or the like. A mask layer 226 is formed over the top electrode layer 224. The mask layer 226 is similar to the mask layer 110 with respect to FIG. 6 in terms of composition and formation method thereof. After the mask layer 226 is formed and patterned, the top electrode layer 224 and the ferroelectric layer 222 are etched using the mask layer 226 as an etch mask, exposing the first ILD layer 206, one of the source/drain contacts 208, a portion of the bottom electrode 218 and the conductive feature 220. The mask layer 226 is then removed such as using plasma ashing process. The resulting structure is shown in FIG. 8G. Remaining portions of the top electrode layer 224 can be referred to as a top electrode 230. Remaining portions of the ferroelectric layer 222 can be referred to as ferroelectric layer 228. The top electrode 230, the ferroelectric layer 228 and the bottom electrode 218 can be collectively referred to as metal-ferroelectric-metal (MFM) structure 232.

Reference is made to FIG. 8H. A second ILD layer 234 is then formed over the first ILD layer 206. The second ILD layer 234 can be similar to the first ILD layer 206 in terms of composition and formation methods. The vias 236 are located above and contacts the corresponding source/ drain contacts 208. The vias 238, 240 are located above and contacts the bottom electrode 218 and the top electrode 230, respectively. One or more of the vias 238, 240 may vertically overlap with the channel region 225. A metal line 242 can be formed over the via 238 and electrically couples the via 238, the gate contact 212 and the gate electrode g1. The metal line 244 is arranged over the via 236 and electrically couples the conductive feature 220 and the source region s1. The metal line 246 is arranged over the via 236 and electrically couples the drain region d1. The metal line 248 is arranged over the top electrode 230 and the ferroelectric layer 228 to be electrically coupled to the top electrode 230 and the ferroelectric layer 228. In the present embodiment, the metal lines 242, 244, 246, 248 can include a metal, such as tungsten (W) or other suitable material such as aluminum (Al), copper (Cu), cobalt (Co), or the like. Formation methods of the metal lines 242, 244, 246, 248 and the vias 236, 238, 240 may include forming openings in the second ILD layer 234, depositing an adhesion layer (not shown), a barrier layer (not shown) and a conductive layer over the openings, forming a mask layer over the conductive layer and patterning the adhesion layer, the barrier layer and the conductive layer using the mask layer as an etch mask, exposing the second ILD layer 234. The adhesion layer, the barrier layer and the conductive layer may be similar to the adhesion layer, the barrier layer and the conductive layer discussed previously with respect to FIG. 8B.

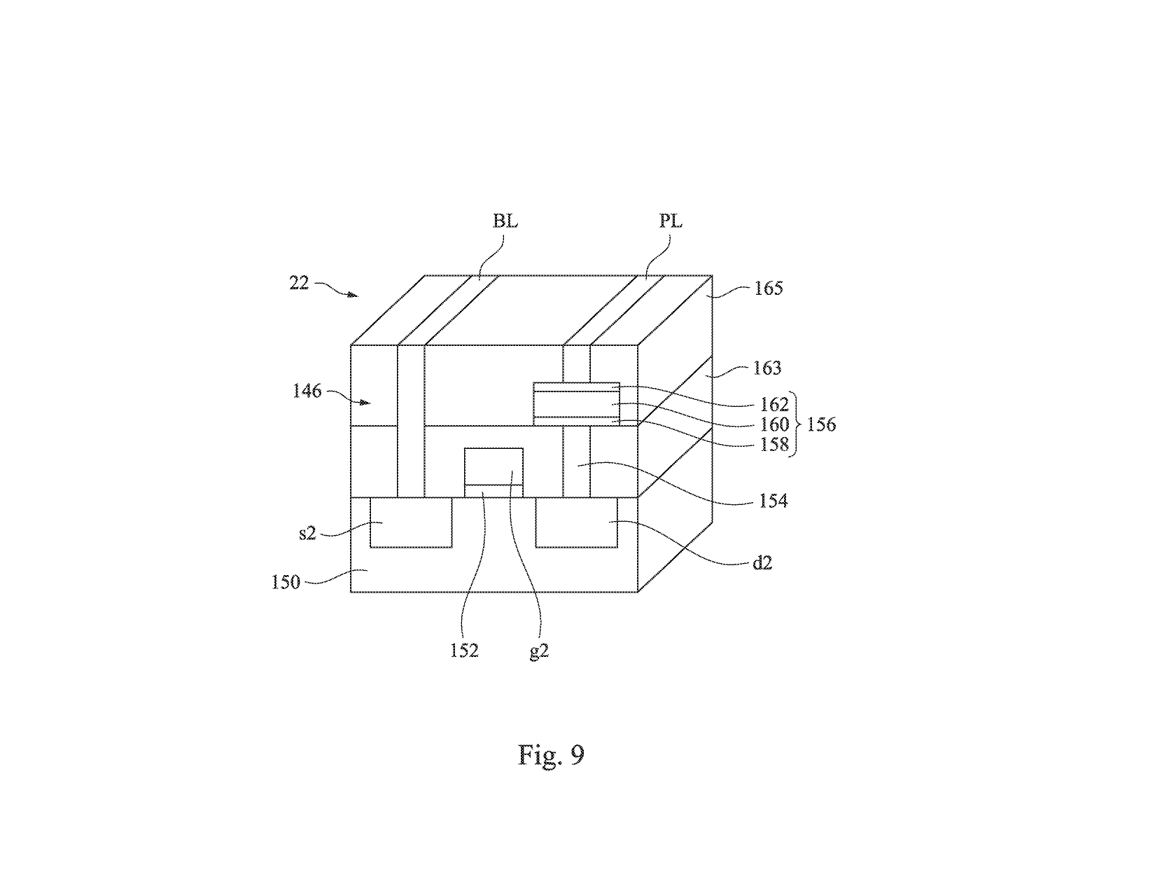

Fig. 9 illustrates a perspective view of an integrated chip 22 having an FeRAM device. The integrated chip 22 includes a one-transistor-one-resistor (1T1R) memory cell architecture having an access device 146 connected to an FeRAM device 148. The access device 146 is formed over a substrate 150. In some embodiments, the access device 146 may include a Metal-Oxide-Semiconductor Field-Effect Transistor (MOSFET) device having a gate electrode g2 that is arranged between a source region s2 and a drain region d2 and that is separated from the substrate 150 by a gate dielectric 152. In other embodiments, the access device 146 may include a high electron mobility transistor (HEMT), a bipolar junction transistor (BJT), or the like.

A dielectric layer163 may be formed over the substrate 150, the gate electrode g2 and the source/drain regions s2/d2. A dielectric layer 165 may be formed over the dielectric layer 163. The dielectric layers 163 and 165 may be similar to the first ILD layer 206 and the second ILD layer 234 in terms of composition and formation method, respectively. One or more interconnect layers include a bit line BL that is electrically coupled to the source region s2. The one or more interconnect layers may further include a drain contact 154, an MFM structure 156 and a power line PL that are electrically connected to the drain region d2. The MFM structure 156 includes a bottom electrode 158 and a top electrode 162 separated from each other by a ferroelectric layer 160, which acts as a data storage layer. The bottom electrode 158 is connected to the drain region d2 by the drain contact 154. The top electrode 162 is coupled to the power line PL. The MFM structure 156 is similar to the MFM structure 107 with respect to FIG. 7A in terms of composition and formation method thereof. That is, the ferroelectric layer 104 in the MFM structure 156 can be formed with high remnant polarization (Pᵣ) without using an anneal process. Although the integrated chip 22 illustrates the word-line WL, the source-line SL, the bit-line BL, the power-line PL and the MFM structure 156 as being located at certain levels within a BEOL (back-end-of-the-line) stack, it will be appreciated that the positon of these elements is not limited to those illustrated positions. Rather, the elements may be at different locations within a BEOL stack. For example, in some alternative embodiments, the MFM structure 156 may be located between a second and third metal interconnect wire.

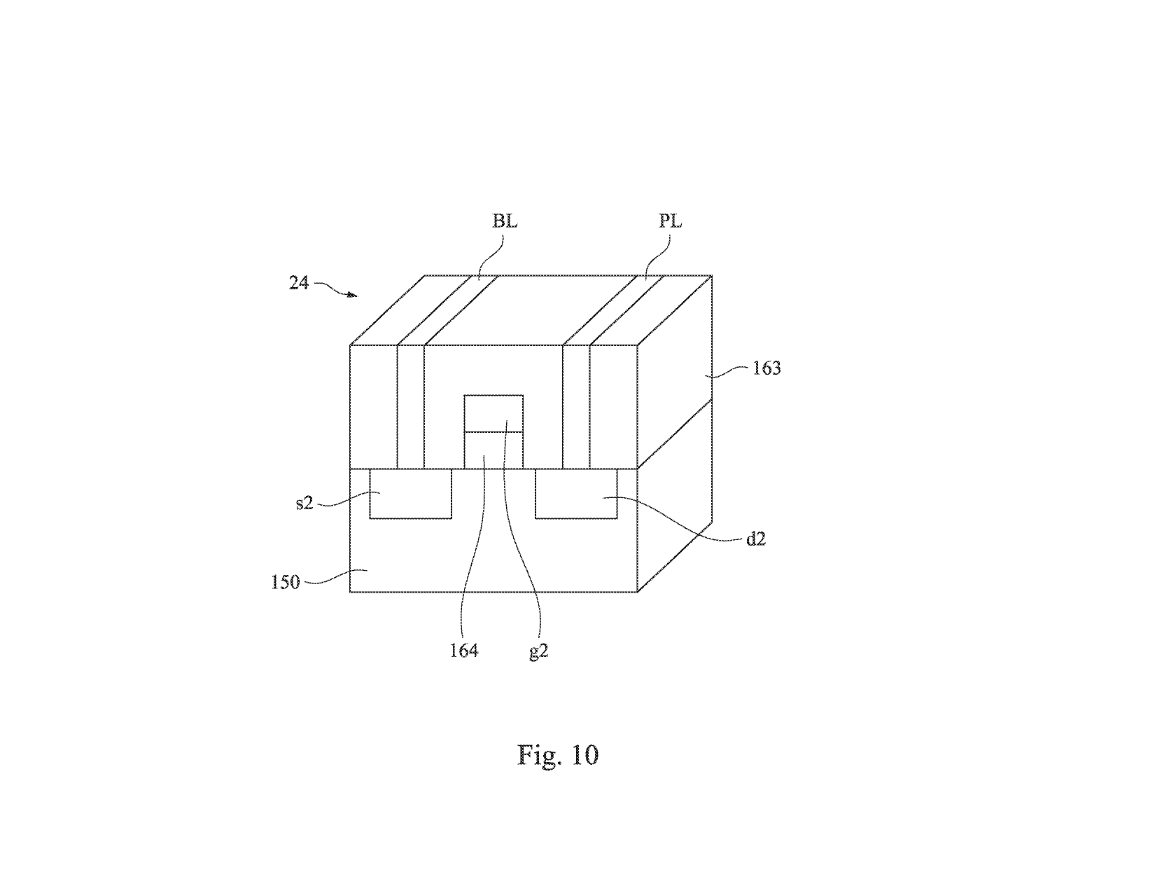

Fig. 10 illustrates a perspective view of an FeFET device 24 in accordance with some embodiments. The FeFET device 24 includes a substrate 150 and heavily doped source region s2 and the drain region d2 separated by the substrate 150, thereby forming a channel region therebetween. The FeFET device 24 further includes a ferroelectric layer 164 covering the channel region separating the source region s2 and the drain region d2. The FeFET device 24 further includes a gate g2 covering the ferroelectric layer 164. The bit line BL is electrically coupled to the source region s2. The power line PL is electrically coupled to the drain region d2. A dielectric structure 163 may be formed over the substrate 150 and the gate g2.

When the gate g2 is biased with a voltage V_{G} relative to the source region s1 and the drain region d1 such that the ferroelectric layer 164 is polarized in a given direction (in this example from the gate toward the bulk), the channel region become low-resistance, corresponding to one memory state (e.g., “1”), and a drain current (I_{D}) from the source region s1 to the drain region d1 is permitted to flow under the source-to-drain bias; in contrast, when the gate g2 is biased relative to the source region s1 and the drain region d1 such that the ferroelectric layer 164 is polarized in the opposite direction (in this example toward the gate from the bulk), the channel region become high-resistance, corresponding to a different memory state (e.g., “0”), and a drain current (I_{D}) from the source region to the drain region is not permitted to flow (or only a small current flows) under the source-to-drain bias.

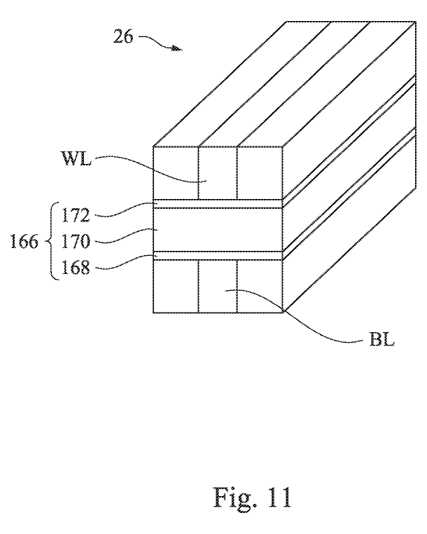

Fig. 11 illustrates a perspective view of an integrated chip having an ferroelectric tunnel junction (FTJ) 26 in accordance with some embodiments. The FTJ 26 may include a metal-ferroelectric-metal (MFM) structure 166, including a ferroelectric layer 170 disposed between two metallic layers (e.g., electrodes) 168, 172. A word-line WL may be electrically coupled to a first one of the metallic layer 172, and a bit-line BL may be electrically coupled to a second one of the metallic layer 168. The MFM structure 166 is similar to the MFM structure 107 with respect to FIG. 7A in terms of composition and formation method thereof. That is, the ferroelectric layer 170 in the MFM structure 166 can be formed with high remnant polarization (Pᵣ) without using an anneal process.

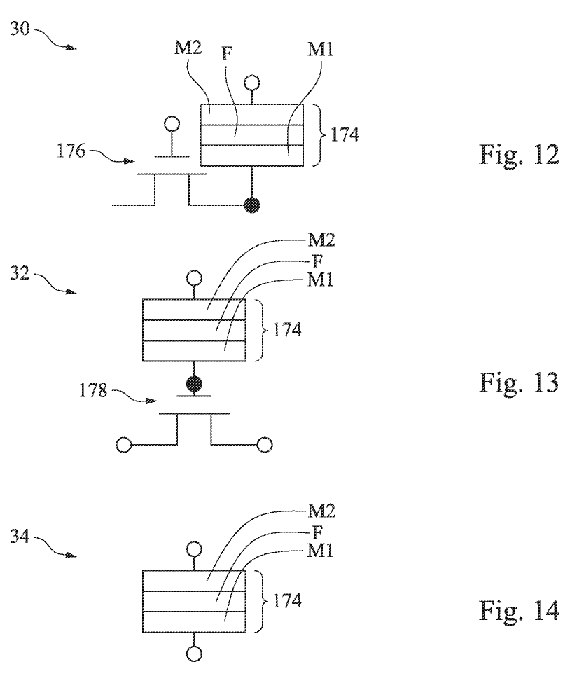

FIGS. 12-14 show cross-sectional view of devices including MFM structures in accordance with some embodiments. Reference is made to FIG. 12. An FeRAM 30 including an MFM structure 174 is shown. The MFM structure 174 includes a bottom electrode M1, a top electrode M2 and a ferroelectric layer F sandwiched between the bottom electrode M1 and the top electrode M2. The FeRAM 30 further includes a transistor 176 connected to the MFM structure 174. For example, the MFM structure 174 is electrically coupled to a source/drain region of the transistor 176. Reference is made to FIG. 13. A ferroelectric memory field-effect transistor (FeMFET) 32 including an MFM structure 174 is shown. The FeMFET 32 further includes a transistor 178 connected to the MFM structure 174. Reference is made to FIG. 14. An FTJ structure 34 is shown. The FTJ structure 34 includes the MFM structure 174 in which metal lines (not shown) can be electrically connected to the MFM structure 174 through the top electrode M1 and the bottom electrode M2 of the MFM structure 174. The MFM structures 174 of the FeRAM 30, the FeMFET 32 and the FTJ structure 34 are similar to the MFM structure 107 with respect to FIG. 7A in terms of composition and formation method thereof.

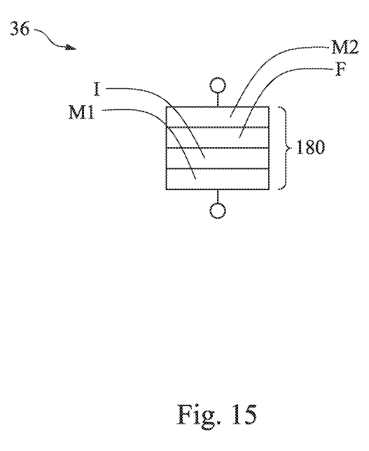

FIG. 15 shows a cross-sectional view of a device including metal-ferroelectric-insulator-metal (MFIM) structure in accordance with some embodiments. The MFIM structure 180 can be used as an FTJ device. The MFIM structure 180 is similar to the MFM structure 174 with respect to FIGS. 12-14 in terms of composition and formation method thereof, except for further including an insulator layer I between the bottom electrode M1 and the ferroelectric layer F. In some embodiments, the insulator layer can include AlOₓ, HfO_{X}, the like, or a combination thereof.

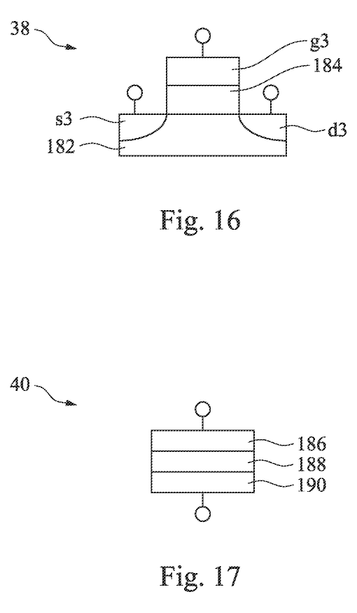

FIG. 16 shows a cross-sectional view of a device including metal-ferroelectric-substrate (MFS) structure in accordance with some embodiments. An FeFET device 38 includes a source region s3, a drain region d3 separated by a substrate 182 and includes a ferroelectric layer 184 and a gate g3 over the ferroelectric layer 184. The ferroelectric layer 184 and the gate g3 are similar to the ferroelectric layer 104 and the top electrode layer 106 of the MFM structure 107 with respect to FIG. 7A in terms of composition and formation method thereof. FIG. 17 shows a cross-sectional view of a device including metal-ferroelectric-substrate (MFS) structure in accordance with some embodiments. A device 40 includes an FTJ structure including a ferroelectric layer 188 and a metal layer 186 stacked in sequence over a substrate 190 in sequence. The substrates 182, 190 can include SiGe, BEOL oxide semiconductor, or the like. The ferroelectric layer 184 is similar to the ferroelectric layer 104 of the MFM structure 107 with respect to FIG. 7A in terms of composition and formation method thereof.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that performing the plasma treatment can allow the ferroelectric layer to have ferroelectricity without using an additional anneal process and allow the ferroelectric layer to keep high remnant polarization (Pᵣ) with low leakage current. Another advantage is that since the ferroelectric layer can be formed with desired remnant polarization (Pᵣ) and low leakage current without using an anneal process, large memory window including low leakage performance and less metal oxidation concern can be achieved. Yet another advantage is that the manufacturing yield can be improved. BEOL FeMFET application can be fulfilled.

In some embodiments, a method of forming a semiconductor device includes the followings steps. A bottom electrode is formed over a substrate. A deposition process including one or more repetitions of a deposition cycle is performed to form a ferroelectric layer over the bottom electrode. The deposition process comprises performing a first deposition step including pulsing a first metal-containing precursor, pulsing a first oxidant reacting with the first metal-containing precursor to form a first monolayer, and performing a first plasma treatment to the first monolayer, and performing a second deposition step including pulsing a second metal-containing precursor, pulsing a second oxidant reacting with the second metal-containing precursor to form a second monolayer, and performing a second plasma treatment to the second monolayer. A top electrode is formed over the ferroelectric layer. In some embodiments, the first plasma treatment is performed using an inert gas. In some embodiments, the second plasma treatment is performed using an inert gas. In some embodiments, the first monolayer and the second monolayer have different compositions. In some embodiments, the ferroelectric layer has a first element having a first atomic concentration and a second element having a second atomic concentration, wherein the second atomic concentration is substantially the same as the first atomic concentration. In some embodiments, the first element includes Hf, and the second element includes Zr. In some embodiments, the bottom electrode and the top electrode comprise ruthenium. In some embodiments, the bottom electrode and the top electrode comprise TiN, Pt, or a combination thereof. In some embodiments, the ferroelectric layer has a thickness in a range from about 2 nm to about 7 nm.

In some embodiments, a method of forming a semiconductor device includes the following steps. A bottom electrode is formed over a substrate. A variable resistance layer is formed over the bottom electrode. Forming the variable resistance layer includes repeating a deposition cycle including a first deposition step and a second deposition step, and forming a top electrode over the variable resistance layer, wherein no anneal process is performed after forming the variable resistance layer over the top electrode and before forming the top electrode over the variable resistance layer. In some embodiments, the first deposition step comprises pulsing a first metal organic precursor, pulsing a first oxidant to react with the first metal organic precursor to form the first monolayer, purging the first metal organic precursor and the first oxidant, and performing a first plasma treatment on the first monolayer. In some embodiments, the first plasma treatment is performed using a gas non-reactive to the first metal organic precursor and the first oxidant. In some embodiments, the second deposition step comprises pulsing a second metal organic precursor, pulsing a second oxidant to react with the second metal organic precursor to form the second monolayer, purging the second metal organic precursor and the second oxidant, and performing a second plasma treatment on the second monolayer. In some embodiments, the second plasma treatment is performed using a gas non-reactive to the second metal organic precursor and the second oxidant. In some embodiments, the variable resistance layer comprises hafnium zirconium oxide. In some embodiments, the hafnium zirconium oxide in the variable resistance layer has a hafnium atomic concentration and a zirconium atomic concentration substantially the same as the hafnium atomic concentration. In some embodiments, the variable resistance layer has a remnant polarization in a range from about 18 µC/cm²to about 20 µC/cm².

In some embodiments, a semiconductor structure includes a substrate, a bottom electrode over the substrate, a ferroelectric layer over the bottom electrode and a top electrode over the ferroelectric layer. The ferroelectric layer comprises a hafnium atomic concentration and a zirconium atomic concentration substantially the same as the hafnium atomic concentration. In some embodiments, the bottom electrode and the top electrode comprise ruthenium. In some embodiments, the bottom electrode and the top electrode comprise TiN, Pt, or a combination thereof.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, comprising:
forming a bottom electrode over a substrate;
performing a deposition process including one or more repetitions of a deposition cycle to form a ferroelectric layer over the bottom electrode, wherein the deposition process comprises:
performing a first deposition step including pulsing a first metal-containing precursor, pulsing a first oxidant reacting with the first metal-containing precursor to form a first monolayer, and performing a first plasma treatment to the first monolayer; and
performing a second deposition step including pulsing a second metal-containing precursor, pulsing a second oxidant reacting with the second metal-containing precursor to form a second monolayer, and performing a second plasma treatment to the second monolayer; and
forming a top electrode over the ferroelectric layer.

2. The method of claim 1, wherein the first plasma treatment is performed using an inert gas.

3. The method of claim 1, wherein the second plasma treatment is performed using an inert gas.

4. The method of claim 1, wherein the first monolayer and the second monolayer have different compositions.

5. The method of claim 1, wherein the ferroelectric layer has a first element having a first atomic concentration and a second element having a second atomic concentration, wherein the second atomic concentration is substantially the same as the first atomic concentration.

6. The method of claim 5, wherein the first element includes Hf, and the second element includes Zr.

7. The method of claim 1, wherein the bottom electrode and the top electrode comprise ruthenium.

8. The method of claim 1, wherein the bottom electrode and the top electrode comprise TiN, Pt, or a combination thereof.

9. The method of claim 1, wherein the ferroelectric layer has a thickness in a range from about 2 nm to about 7 nm.

10. A method of forming a semiconductor device, comprising:
forming a bottom electrode over a substrate;
forming a variable resistance layer over the bottom electrode, wherein forming the variable resistance layer comprises:
repeating a deposition cycle including a first deposition step and a second deposition step; and
forming a top electrode over the variable resistance layer, wherein no anneal process is performed after forming the variable resistance layer over the top electrode and before forming the top electrode over the variable resistance layer.

11. The method of claim 10, wherein the first deposition step comprises:
pulsing a first metal organic precursor;
pulsing a first oxidant to react with the first metal organic precursor to form a first monolayer;
purging the first metal organic precursor and the first oxidant; and
performing a first plasma treatment on the first monolayer.

12. The method of claim 11, wherein the first plasma treatment is performed using a gas non-reactive to the first metal organic precursor and the first oxidant.

13. The method of claim 11, wherein the second deposition step comprises:
pulsing a second metal organic precursor;
pulsing a second oxidant to react with the second metal organic precursor to form a second monolayer;
purging the second metal organic precursor and the second oxidant; and
performing a second plasma treatment on the second monolayer.

14. The method of claim 13, wherein the second plasma treatment is performed using a gas non-reactive to the second metal organic precursor and the second oxidant.

15. The method of claim 11, wherein the variable resistance layer comprises hafnium zirconium oxide.

16. The method of claim 15, wherein the hafnium zirconium oxide in the variable resistance layer has a hafnium atomic concentration and a zirconium atomic concentration substantially the same as the hafnium atomic concentration.

17. The method of claim 11, wherein the variable resistance layer has a remnant polarization in a range from about 18 µC/cm²to about 20 µC/cm².

18. A semiconductor structure, comprising:
a substrate;
a bottom electrode over the substrate;
a ferroelectric layer over the bottom electrode, wherein the ferroelectric layer comprises a hafnium atomic concentration and a zirconium atomic concentration substantially the same as the hafnium atomic concentration; and
a top electrode over the ferroelectric layer.

19. The semiconductor structure of claim 18, wherein the bottom electrode and the top electrode comprise ruthenium.

20. The semiconductor structure of claim 18, wherein the bottom electrode and the top electrode comprise TiN, Pt, or a combination thereof.
